(19) United States
(12) Patent Application Publication
(10) Pub. No.: US 2020/0146175 A1
(43) Pub. Date: May 7, 2020

(54) Thermal Sticker For Cooling Hot Spots In Cellular Phones

(71) Applicant: James Hirschfeld, Delray Beach, FL (US)

(72) Inventor: James Hirschfeld, Delray Beach, FL (US)

(21) Appl. No.: 16/721,842

(22) Filed: Dec. 19, 2019

Related U.S. Application Data
(63) Continuation-in-part of application No. 15/707,986, filed on Sep. 18, 2017, now abandoned.

(51) Int. Cl. H05K 7/20

(52) U.S. Cl. CPC H05K 7/2029

(57) ABSTRACT

A removable thermal sticker secured to the surface of a cellular phone for extraction of heat from the cellular phone. The thermal sticker is thin and sized to be conveniently carried. The thermal sticker is adhered to the cellular phone at its hot spot for maximum efficiency. An optional feature employs thermal strips that indicate when the electronic device is exceeding a temperature threshold.

### CROSS-REFERENCE TO RELATED APPLICATIONS

This application is related to, and claims the benefit of, the provisional patent application, now expired, entitled “Apparatus and Method for Cooling Portable Electronic Devices”, filed Nov. 25, 2014, bearing U.S. Ser. No. 62/084,331 and naming James Hirschfeld, the named inventor herein, as sole inventor; the currently abandoned non-provisional patent application, entitled “Apparatus and Method for Cooling Portable Electronic Devices”, filed Jul. 21, 2015, bearing U.S. Ser. No. 14/805,224 and naming James Hirschfeld, the named inventor herein, as sole inventor; and the currently pending continuation-in-part non-provisional patent application, entitled “Cooling Sticker For Cooling Hot Spots In Cellular Telephones”, filed Sep. 18, 2017, bearing U.S. Ser. No. 15/707,986 and naming James Hirschfeld, the named inventor herein, as sole inventor, the contents of each is specifically incorporated by reference herein in its entirety.

### BACKGROUND

### Technical Field

This invention relates in general to cellular phones. In particular, it relates to a disposable thermal sticker that adheres to the exterior of a cellular phone above the battery. The thermal sticker extracts heat from the surface of the cellular phone and prevents the cellular phone from overheating, and optionally provides a thermal strip to give a visual indication of the device's temperature so that the individual using a cellular phone will have an indication when the thermal sticker needs to be installed or replaced because the cellular phone is overheating.

### BACKGROUND OF THE INVENTION

The vast majority of people use cellular phones on a regular basis. Since these devices are typically battery-powered, the internal power supply often results in generation of substantial undesirable heat. In addition, while these devices provide substantial convenience and productivity advantages for individuals, they are often used in environments where it is difficult to control ambient temperature. As a result, overheating frequently causes problems for the user, such as errors, data loss, device shutdown, and even damage to the device due to overheating.

The prior art attempted to address heating problems in electronic devices in several ways. One such attempt has been the use of supports, such as platforms, that contain integral fans that direct enhanced airflow to the bottom of the portable electronic device. These devices have several disadvantages. In particular, fan based platforms typically require the platform to be plugged into a power source such as a wall outlet, and due to that, a fan based platform system would be entirely unsuitable for devices such as a cellular phone. It would be desirable to have a method of cooling cellular phones without regard to their location, and while they are used in a mobile environment, such as outdoors in ho weather, which may subject them to overheating problems.

It would be further desirable to have a method of cooling a cellular phone that is small in size and weight, such that it is convenient for users to carry.

Due to the foregoing drawbacks of the prior art, existing cooling devices are not used when traveling. This is not desirable when ambient temperatures are such that heat is a problem. It would be desirable to have a cooling device that could be easily and conveniently attached to a cellular phone only when it is needed. Likewise, it would be desirable to have a method of replenishing a portable cooling device when needed. For example, when a cellular phone is used indoors or in an air conditioned environment, cooling may not be needed, but when used in a warm environment, such as outdoors in summer, it would be useful.

An alternative to fixed location fan-based cooling systems is the use of commercially available “blue ice” cooling blocks. While these cooling blocks are portable, they typically have substantial bulk and weight. As a result, they are too bulky, heavy, and inconvenient for use in conjunction with a cellular phone, and would only be appropriate for large electronic devices. It would be desirable to have a cooling device that is small enough and light enough such that the user could conveniently carry multiple cooling devices.

It would be desirable to have a cooling mechanism that is in direct contact with the surface of the hotspot on the cellular phone to ensure the maximum effectiveness of heat transfer. On cellular phones, a hotspot is most often found near the location of the battery. It would be desirable to have a cooling device that can be attached to a specific location on the cellular phone, such as the location of the battery. Because the cooling device would be more effective if sized and placed on the hot spot of a cellular phone rather than over a larger area that doesn't require cooling. Further, a cooling device having a reduced size would allow multiple cooling devices to be carried, for example, in a cellular phone owner's pocket, as well as allowing convenient replacement of the cooling device.

While the prior art has provided various solutions to the problem of overheating larger electronic devices, the prior art solutions are typically bulky, heavy, and require either an external power source, or are only useful while the large heavy cooling block is in a fixed location. None of them provide an effective solution for cellular phones. It would be desirable to have a device that effectively cools the cellular phone while having low weight, small size, and portability.

### SUMMARY OF THE INVENTION

This invention provides a removable thermal sticker that can be secured to the surface of a cellular phone to extract heat from it. The thermal sticker is preferably fabricated using phase change material that has an insulation layer furthest from the surface in contact with the cellular phone. The surface in contact with the cellular phone is preferably fabricated with an efficient thermal conductor such as a metalized foil. Between the insulation layer and the metalized layer is a core layer of lightweight graphene nano-platelets and polyaniline. The thermal sticker is thin and sized to fit electronic devices of many sizes. In the preferred embodiment, the thermal sticker is generally similar in size and weight to a conventional band aid used for first aid, and can come in a variety of sizes. Further, one or more thermal stickers are independently attachable to the surface of a cellular phone at the cellular phone's hot spot(s) for maximum efficiency. A further optional feature employs a thermal strip that indicates when the electronic device is exceeding a temperature threshold.

### BRIEF DESCRIPTION OF THE DRAWINGS

FIG. 1 illustrates a bottom plan view of a preferred embodiment of a cellular phone showing a hot spot.

FIG. 2 illustrates a bottom plan view of a preferred embodiment of a cellular phone with a thermal sticker secured to its rear surface above the hot spot.

FIG. 3 illustrates an edge view of a preferred embodiment of the thermal sticker showing a layered structure.

FIG. 4 illustrates a bottom plan view of a cellular phone with a thermal strip for indicating the temperature of the device.

### DETAILED DESCRIPTION OF THE PREFERRED EMBODIMENT

Prior to a discussion of the figures, a general overview of the invention will be provided. The invention provides thermal stickers that can be secured to the surface of a cellular phone much like a Band-Aid™ secures to an individual's skin. The thermal stickers are thin and lightweight which allows multiple thermal stickers to be carried for use as needed. When a user determines that the cellular phone in use is running hot or beginning to overheat, the thermal sticker is secured to the electronic device for the purpose of transferring heat out of the device. Likewise, an optional thermal strip can be attached to the cellular phone to indicate its temperature. Thermal strips are well known in the art.

An additional advantage of using thermal stickers that are adhered to the surface of the cellular phone is that the thermal sticker can be applied to the surface at the precise point where heat is greatest rather than applying the pad to the entire device such that it covers areas that do not need cooling. The thermal stickers provide an extended period of time to prevent electronic devices from overheating. This can be important when the device is in a hostile environment, such as outdoors in hot weather.

The physical size of the thermal sticker is an important advantage of the invention because it is very thin and lightweight. This allows multiple thermal stickers to be carried so that the cooling time can be extended for longer periods of time. The small size of the thermal stickers allows them to be conveniently carried in a computer bag, a phone cover, a briefcase, a wallet, a pocket, etc., until they are needed.

In a preferred embodiment, the thermal stickers are constructed of thermal-composites and insulation that serve to transfer excess heat from the cellular phone to bring the devices temperature into its thermal operating profile range.

A preferred embodiment uses chemical thermal stickers that the user activates when needed. The chemical reaction in the thermal stickers provides cooling to the cellular phone when they are attached to the cellular phone. An advantage of this embodiment is that it does not require any external power and requires a minimum amount of space. Preferably, the thermal sticker would be 1/16 of an inch thick. However, the thickness can vary based on the amount of cooling capacity desired.

Depending on the type of cellular phone being used, the surface area will vary. The size selected by the user would depend on the particular cellular phone in question. Of course, thermal stickers for smaller devices would require less surface area to be covered. The advantage of a chemical-based thermal sticker is that it does not require any external power source. Once the chemical reaction is complete, and the thermal sticker starts to decline in effectiveness, it can be peeled off of the surface of the cellular phone and replaced with a fresh thermal sticker. Being able to replace the thermal stickers at will allows a cellular phone to have an extended cooling period when traveling or in a hostile outdoor environment.

In a preferred embodiment, the thermal sticker is fabricated using phase change material (PCM) that changes from solid to liquid and then back for the purpose of storing and releasing large amounts of thermal energy. In addition, thermal composites can be used that combine PCMs with other solid structures, such as copper mesh immersed in paraffin. PCMs have a high heat of fusion. Because of that, they change from solid to liquid based on exposure to varying levels of heat. The process of melting and solidifying at a certain temperatures allows PCMs to store and release significant amounts of thermal energy. Heat is absorbed or released when the material changes between solid and liquid states.

The preferred embodiment envisions an optional insulation layer on the surface of the thermal sticker (the distal surface) that is opposite to the surface in contact with the device (the proximal surface). The preferred embodiment uses commercially available Lumira aerogel™ in particle or pellet form. The insulation layer is preferably fabricated with Lumira aerogel and insulates the thermal strip from the outside environment.

In addition, the proximal surface of the thermal sticker preferably has a metalized Mylar or other suitable foil material to maximize heat transfer from the cellular phone to the core layer of the thermal sticker. Preferably, the metalized Mylar or other suitable foil material is secured to the surface of the cellular phone with an adhesive material or other suitable means that allow the thermal sticker to be removably attached to the cellular phone.

The thermal sticker structure has a core layer of PCM material between the distal and proximal layers of the thermal sticker. The core layer is fabricated from lightweight polyaniline, commercially available from Sigma-Aldrich™, and graphene nano-platelets, commercially available from xGnP™.

The thermal sticker can be attached to a cellular phone by any suitable means, such as adhesive, double stick tape, etc.

An optional feature of the invention provides an integrated liquid crystal thermometer that provides the user with the visual indication of the current temperature of the electronic device. Liquid crystal thermometers are commercially available from a wide variety of sources, and are typically encased in a plastic strip that changes color to indicate different temperature ranges. They provide an advantage in that they are small, thin, and lightweight. They can be integrated with the thermal sticker or installed as a separate unit.

Having discussed the invention in general, we turn now to a detailed discussion of the figures.

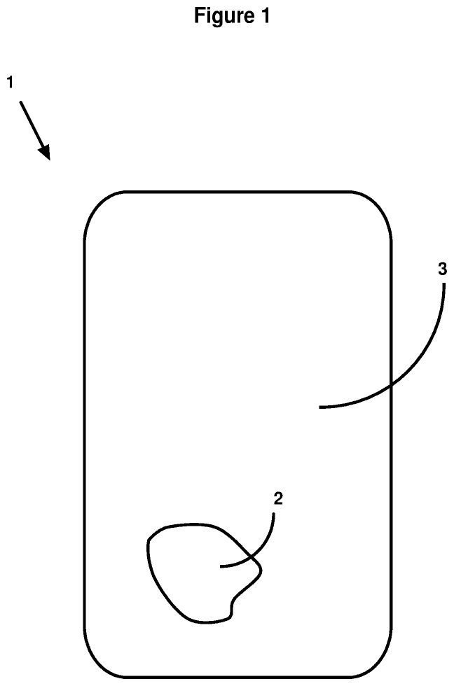

FIG. 1 illustrates a bottom plan view of a preferred embodiment of a cellular phone 1 showing a hot spot 2 on the bottom surface 3 of the cellular phone 1. Hot spots 2 can be caused by heat from the battery or other components of the cellular phone 1 that tend to produce the most heat. Electronic devices such as cellular phones 1 need to operate within a predetermined temperature range, and heat will adversely affect the device's performance. However, heat is often limited to a relatively small area of the cellular phone, usually by the battery. As shown in this figure, the hot spot 2 is concentrated in only a portion of the cellular phone 1, but that is often all that is needed to cause device failure.

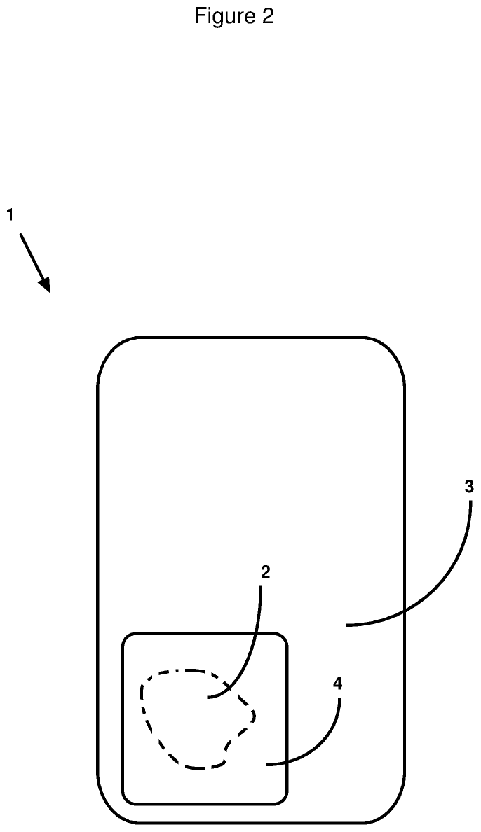

FIG. 2 illustrates a bottom plan view of a preferred embodiment of a cellular phone 1 showing a thermal sticker 4 secured over the hot spot 2 (shown in dashed lines in this figure). In this configuration, the thermal sticker 4 draws heat from the hot spot 2, while the rest of the cellular phone 1, which is not excessively hot, does not require any thermal relief.

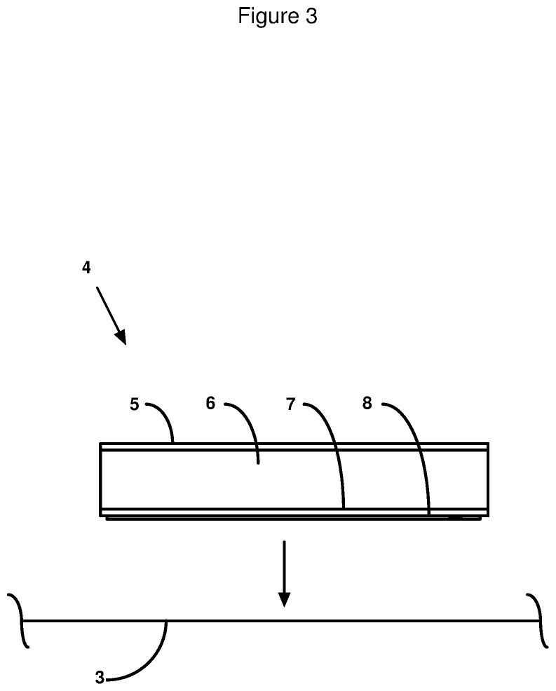

FIG. 3 illustrates an edge view of a preferred embodiment of the thermal sticker 4 showing the layered structure. The insulation layer 5 is shown on the distal surface of the thermal sticker 4. Beneath that is the core layer 6 that absorbs heat from the cellular phone 1. On the proximal surface of the thermal sticker 4 is the heat transfer layer 7 that can be a metalized Mylar or other suitable material with a high thermal conductivity to maximize heat transfer from the cellular phone 1 to the core layer 6. An attachment layer 8 is also shown. The attachment layer 8 secures the thermal sticker 4 to the cellular phone 1. Any form of suitable adhesive can be used so long as it allows the thermal sticker 4 to be conveniently installed and removed.

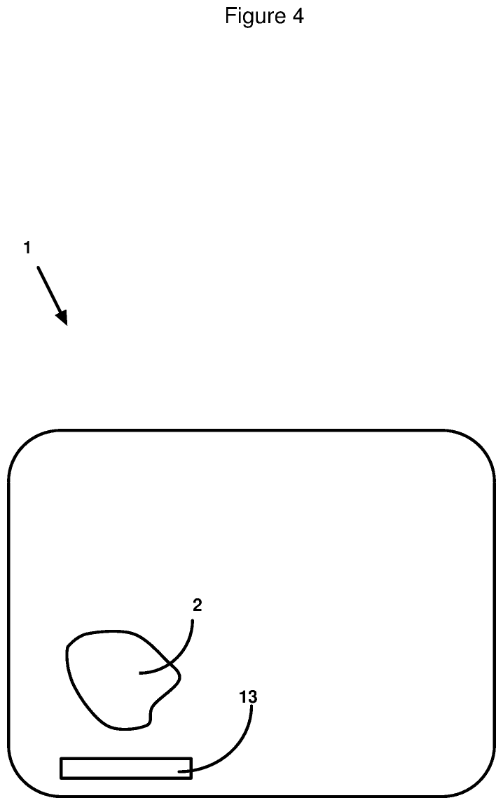

FIG. 4 illustrates a rear view of a cellular phone 1 with a thermal strip 13 for indicating the temperature of the cellular phone 1 at the location that is prone to heat, typically at the location of the battery. This figure shows the thermal strip 13 secured directly to the surface of the cellular phone 1. This allows the thermal strip 13 to be permanently mounted to the device 1, if desired. However, those skilled in the art will recognize that the thermal strip 13 could also be integrated as a component of the thermal sticker 4.

While specific embodiments have been discussed to illustrate the invention, it will be understood by those skilled in the art that variations in the embodiments can be made without departing from the scope and spirit of the invention. The types of materials used can vary, the method of attachment can vary, etc. For example, the phase change material can be any PCM material and does not have to be limited to the particular PCM material used above. The material used to fabricate the insulating layer and the heat transfer layer can vary. Therefore, the invention shall be limited solely to the scope of the claims.

I claim:

1. A detachable thermal sticker for cellular phones, comprising:
a detachable thermal sticker sized to fit a hotspot on an cellular phone, such that when the thermal sticker is in contact with the hot spot, heat is transferred from the hotspot to the thermal sticker, the thermal sticker further comprising:
an insulation layer facing away from the cellular phone and attached to a core layer, the insulation layer comprised of insulating material and prevents heat external to the cellular phone from entering the thermal sticker;
the core layer comprised of heat absorbing material;
a heat transfer layer attached to the core layer, the heat transfer layer having thermal conductivity to transfer heat from the cellular phone to the core layer;
an attachment layer attached to heat transfer layer, the attachment layer removably secures the thermal sticker to the cellular phone;
whereby the core layer transfers excessive heat away from the hotspot on the cellular phone to the core layer.

2. A thermal sticker, as in claim 1, wherein:
the core layer is comprised of phase change material.

3. A thermal sticker, as in claim 2, wherein:
the insulation layer secured to the core layer prevents heat external to the cellular phone from warming the core layer.

4. A thermal sticker, as in claim 2, further comprising:
a heat transfer layer secured to the surface of the core layer is comprised of material having thermal conductivity.

5. A thermal sticker, as in claim 4, wherein:
the heat transfer layer is substantially comprised of metalized Mylar.

6. A thermal sticker, as in claim 3, wherein:
the insulation layer is substantially comprised of Lumira Aerogel.

7. A thermal sticker, as in claim 2, wherein:
the phase change material in the core layer is substantially comprised of graphine nano-platelets and polyaniline material.

8. A thermal sticker, as in claim 1, wherein:
the attachment layer on the proximal surface of the thermal sticker is an adhesive.

9. A method of extracting heat from a hotspot on cellular phones, including the steps of:
detachably attaching a thermal sticker over a hotspot on a cellular phone; and
using phase change material in the thermal sticker as an active heat extraction material such that when the thermal sticker is in contact with the hot spot, heat is transferred from the hotspot into the phase change material in the thermal sticker;
whereby the phase change material transfers heat from the hotspot on the cellular phone to the thermal sticker.

10. A method, as in claim 9, including the additional step of:
using graphine nano-platelets and polyaniline material as the phase change material.

11. A method, as in claim 10, including the additional step of:
using a layer of material having a high thermal conductivity as an intermediary layer between the phase change material and the cellular telephone.

12. A method, as in claim 11, including the additional step of:
using metalized Mylar as the layer of material having thermal conductivity.

13. A method, as in claim 11, including the additional step of:
using an adhesive attachment layer between the intermediary layer and the cellular phone such that the thermal sticker is removably attached to a cellular phone.

14. A method, as in claim 11, including the additional step of:
using Lumira Aerogel to insulate the surface of the thermal sticker that does not come in contact with the cellular phone.
